(19) United States
(12) Patent Application Publication
(10) Pub. No.: US 2004/0002207 A1
(43) Pub. Date: Jan. 1, 2004

(54) Method of ultra low-k device fabrication

(75) Inventor: Chris C. Yu, Conneautville, PA (US)

Correspondence Address: PHYLLIS T. TURNER-BRIM, ESQ., LAW DEPARTMENT, CABOT MICROELECTRONICS CORPORATION, 870 NORTH COMMONS DRIVE, AURORA, IL, 60504, US

(73) Assignee: Cabot Microelectronics Corporation

(21) Appl. No.: 10/361,665

(22) Filed: Feb. 10, 2003

Related U.S. Application Data
(60) Provisional application No. 60/356,240, filed on Feb. 11, 2002.

(51) Int. Cl. H01L 21/4763; H01L 21/31; H01L 21/469

(52) U.S. Cl. 438/622; 438/623; 438/624; 438/631; 438/783

(57) ABSTRACT

A method for fabricating a region of low dielectric constant between metal layers of a substrate, such as an integrated circuit, that eliminate or minimize the problems associated with the existing and future low-k materials and processes. The method utilizes a sacrificial layer or an ultra low-k layer to form a major, but not entire, portion of the dielectric layer between the metal layers, using innovative integration schemes and CMP processes.

### CROSS REFERENCE TO RELATED PATENT APPLICATIONS

This patent application claims priority to U.S. Provisional Patent Application No. 60/356,240, filed on Feb. 11, 2002.

### FIELD OF THE INVENTION

The present invention concerns methods for fabricating a region of low dielectric constant adjacent to metal layers of a substrate, such as an integrated circuit.

### BACKGROUND

As faster and more powerful integrated circuits (“ICs”) are developed, the number of interconnection layers has also increased in order to connect a greater number of transistors on a single chip. This increased number of IC interconnect levels can also increase the accumulative inter-metal layer capacitance of the IC, which can limit device speed. Further, the traditional dielectric material, silicon dioxide or doped silicon dioxide, has a dielectric constant of about 4, a value higher than that of a number of other dielectric materials. Therefore, materials with low dielectric constants (“low-k”) are used between signal levels and between adjacent lines of the same signal level to reduce capacitance to ground and coupling capacitance respectively.

Various low-k materials have been developed in recent years to meet such demand. While integration of medium low-k materials, having k values from about 2.5 to about 3.7, into IC device manufacturing has been demonstrated, there are still significant problems relating to the integration of ultra low-k materials, having k values less than 2.5, into the fabrication of IC devices. One problem is that many existing low-k materials are incompatible with existing integrated circuit manufacturing processes, such as etching, lithography, metal deposition, and chemical mechanical polishing (CMP). For example, IC device fabrication relies upon etch technology to define contact/via holes and trenches (for subsequent metal plug and line formation). With ultra low-k materials, patterning using etch becomes very difficult. In particular, with porous ultra low-k materials, attaining contact/via and trenches with desired etch profile (such as straight etch profile) has been difficult. In another example, in a CMP process, the fracture toughness of low-k materials is less than that of silicon dioxide, so delamination and cracking can occur as multiple levels of metals and dielectrics build up.

Another problem with current ultra low-k materials is the difficulty in attaining truly low-k values while maintaining material integrity. There is also currently difficulty in identifying and developing a viable material with even lower k values of about 1.5.

These problems with the ultra low-k materials ultimately lead to problems with the robustness, repeatability, and manufacturability of the processes used to manufacture IC devices containing these ultra low-k materials. Therefore, a need exists for a new low-k material and processes for integrating currently available low-k materials into IC devices.

### SUMMARY OF THE INVENTION

In one aspect, this invention includes a process for fabricating an integrated circuit having an ultra low-k region. This process includes the steps of forming a substrate having a first material layer; patterning the first material layer to form a plurality of features each having a top surface and to form gaps between features; depositing a first layer of oxide material onto the top surface of the features and into the gaps; depositing a first layer of sacrificial material onto the first layer of oxide material; polishing the first layer of sacrificial material to form a co-planar surface comprising the first layer sacrificial material and the first layer of oxide material on the top surface of the features, wherein sacrificial material remains in the gaps between features; depositing a second layer of oxide material onto the co-planar surface; patterning the second layer of oxide material to create a plurality of void features, wherein at least one void feature exposes a portion of the first material layer; depositing a second material layer onto the top surface of the second oxide layer and into the void features; and removing at least a portion of the first sacrificial material.

Another aspect of this invention, is a process for fabricating an integrated circuit having an ultra low-k region. This process includes forming a substrate having a first material layer; patterning the first material layer to form a plurality of features, each having a top surface, and to form gaps between the features; depositing a first layer of oxide material onto the top surface of the features and into the gaps; depositing a first layer of sacrificial material onto the first layer of oxide material; planarizing the first layer of sacrificial material; patterning the first layer of sacrificial material to form a plurality of void features; depositing a second layer of oxide material onto patterned first layer of sacrificial material and into the void features; planarizing the second layer of oxide material; patterning the second oxide layer to form a plurality of void features wherein at least one void feature exposes a portion of the first material layer; depositing a second material layer onto the second oxide layer and into the void features; polishing the second material layer to form a co-planar surface comprising the second material layer and the second oxide layer, wherein the second material layer remains in the void features; and removing at least a portion of the first sacrificial material layer.

Yet another aspect of this invention, is a process for fabricating an integrated circuit having an ultra low-k region. The process includes the steps of applying a first oxide layer on top of a substrate; patterning the first oxide layer and depositing a first material layer to form a plurality of first material features within the first oxide layer; removing a portion of the first oxide layer between the first material features thereby creating gaps in the first oxide layer; depositing a first sacrificial material layer onto the surface of the patterned first oxide layer and into the gaps within the first oxide layer; polishing the first sacrificial layer to form a co-planar surface comprising the first sacrificial layer and the first oxide layer, wherein the first sacrificial material remains in the gaps; depositing a second oxide layer onto the co-planar surface; patterning the second oxide layer to create a plurality of void features, wherein at least one void feature exposes a portion of the first material layer; depositing a second material layer onto the top surface of the second oxide layer and into the void features, thereby creating second material features; removing a portion of the second material layer from the surface of the second oxide layer; removing a portion of the second oxide layer between the second material features, thereby creating gaps in the second oxide layer; depositing a second sacrificial material layer onto the surface of the patterned second oxide layer and into the gaps within the second oxide layer; polishing the second sacrificial layer to form a coplanar surface comprising the second sacrificial layer and the second oxide layer, wherein sacrificial material remains in the gaps between the second material features; depositing a third oxide layer onto the co-planar surface; patterning the third oxide layer to create a plurality of void features, wherein at least one void feature exposes a portion of the second material layer; removing at least a portion of the first sacrificial material layer and the second sacrificial material layer.

In still another aspect, this invention is a method for fabricating an integrated circuit having an ultra low-k region. The method includes the steps of forming a substrate having a first material layer; patterning the first material layer to form a plurality of features, each having a top surface, and to form gaps between the features; depositing a first layer of oxide material onto the top surface of the features and into the gaps; depositing a first layer of ultra low-k material onto the first layer of oxide material; polishing the first layer of ultra low-k material to form a co-planar surface comprising the first layer of ultra low-k material and the first layer of oxide material on the top surface of the features, wherein ultra low-k material remains in the gaps; depositing a second layer of oxide material onto the co-planar surface; patterning the second oxide material layer to create a plurality of void features, wherein at least one void feature exposes a portion of the first material layer; and depositing a second material layer onto the top surface of the second oxide material layer and into the void features.

### BRIEF DESCRIPTION OF THE FIGURES

FIGS. 1A-G are steps in one embodiment of a process of the present invention;

FIGS. 2A-F are steps in another embodiment of a process of the present invention;

FIGS. 3A-I are steps in yet another embodiment of a process of the present invention;

FIGS. 4A-G are steps in still another embodiment of a process of the present invention.

### DETAILED DESCRIPTION

The present invention concerns methods for fabricating a region of low dielectric constant between metal layers of a substrate, such as an integrated circuit, that eliminate or minimize the current problems associated with manufacturing substrates with low-k materials. The present invention utilizes a sacrificial layer or an ultra low-k layer to form a major, but not entire, portion of the dielectric layer between the metal layers, using innovative integration schemes and CMP processes.

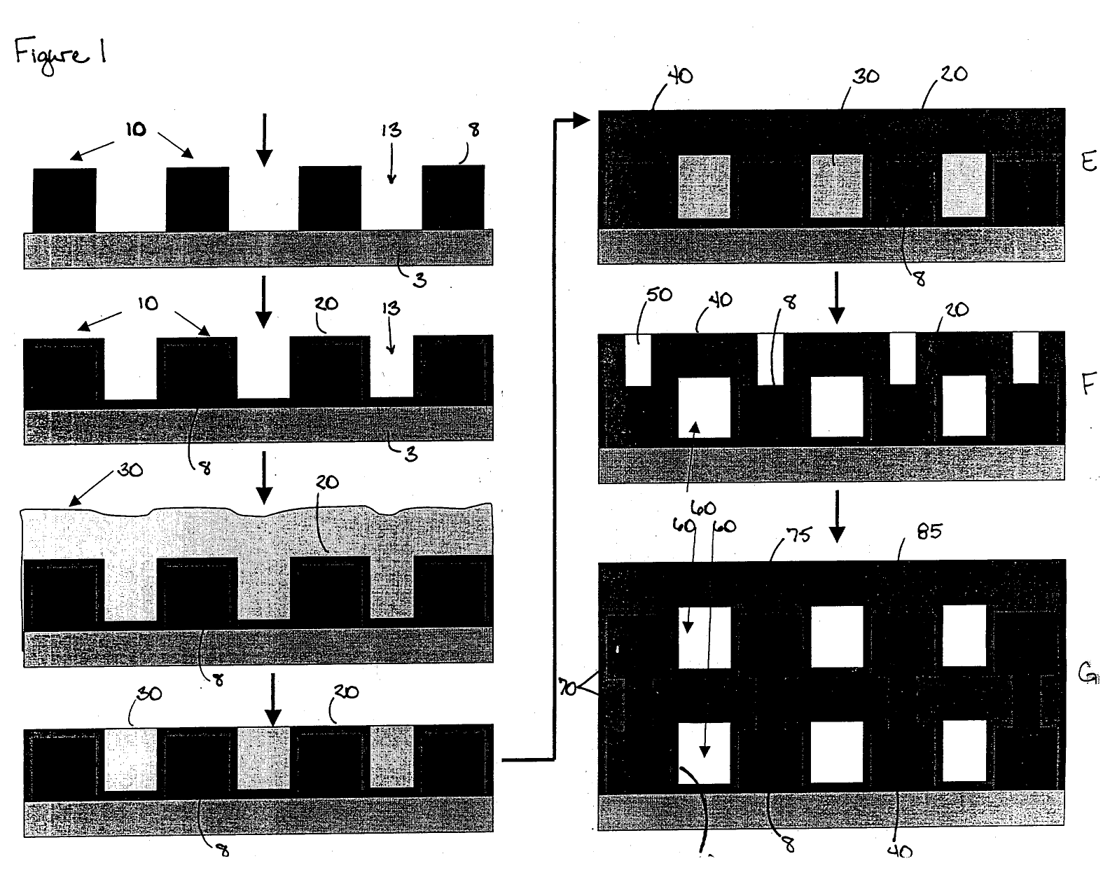

FIGS. 1A-G illustrate an embodiment of a process of the present invention. The process begins with an article including a first material layer 8 on a substrate 3. In FIG. 1A, first material layer 8 is patterned to form a plurality of raised features 10 with gaps 13 between features 10. Raised features 10 are obtained using lithography and plasma etch techniques. Preferably, first material layer 8, and features 10 are composed of conductive materials such as metals or alloys including, but not limited to Al, Cu, W, TiN, Ti, TiW, Ta, TaN, Au and combinations thereof.

In FIG. 1B, a first layer of oxide material 20 is deposited onto the surface of features 10 and on the surface of substrate 3 located in gaps 13. Preferably, oxide material 20 is composed of silicon dioxide or doped silicon dioxide, such as boron-phosphorus-silica-glass (BPSG), fluorinated oxides (FGS), or phosphorus-silica-glass (PSG) and deposited using chemical vapor deposition (CVD). First oxide material layer 20 is, preferably, deposited in a uniform manner such that no void spaces are created between features 10 of first material layer 8 and first oxide layer 20. Most preferably, the deposited first oxide layer 20 is conformal with the patterning of features 10. Generally, the thickness of first oxide layer 20 will range from about 500 Å to about 3000 Å.

In FIG. 1C, a layer of sacrificial material 30 is deposited onto the exposed surface of oxide layer 20. Sacrificial layer 30 should be deposited on oxide layer 20 in an amount that is sufficient to fill gaps 13. The amount or thickness of sacrificial material layer 30 should also be sufficient to achieve planarity of sacrificial material layer 30 after polishing. Generally, the thickness of sacrificial layer 30 will range from about 5000 Å to about 15,000 Å.

Preferably, sacrificial layer 30 is deposited onto first oxide layer 20 of the IC device by a spin-coating or CVD techniques. Most preferably, a precursor of a sacrificial material, typically in liquid form, is first spin-coated onto first oxide layer 20. The sacrificial material is next heated to a desired temperature to drive off solvents in the material, forming a solid, densified layer.

Preferred sacrificial materials 30 are materials exhibiting void-free or conformal properties, having a high molecular weight of about 20,000 Daltons or greater, and able to be deposited and cured at temperatures below 600° C. Materials that can be deposited by spin-coating and that can achieve good planarity after polishing are most preferred. For example, spin-on polymers which have been tested or used in IC device planarization using sacrificial layer etchback, as described in C. Jang et al., Proceedings 4th International IEEE VMIC Conf., p.357 (1987), may be used. Another group of materials that may be utilized are polyimides, such as bis-benzocyclobutenes (BCB) and fluoro-polyimides. The polyimide is typically spun onto the IC device in the form of a liquid and then a high temperature step is used to transform the liquid into a solid polyimide film. Poly(alylene) ethers (PAE), another spin-on polymer, may also be used.

Additionally, polymers, such as BCB, PAE, and fluoro-polyimides, are low-k materials themselves. In general, low-k polymers have better mechanical properties than those of ultra low-k materials and have dielectric constants of about 2.5 to about 3. Therefore, low-k polymers are more suited for IC processing and are also acceptable, even if not completely removed during the sacrificial layer removal step, due to their reasonably low dielectric constant.

Optionally, photoresist materials may be used for sacrificial material 30. A typical photoresist has three components: (1) a matrix material, (2) a photoactive compound which is responsible for photochemical reaction occurring in the resist region upon exposure to light, and (3) a solvent. The type of photoresist that may be used depends largely upon the specific IC device being fabricated. Negative photoresists are typically used for devices having 2 μm feature sizes and above, while positive photoresists are typically used for devices having 0.5 μm to 2 μm feature sizes. For feature sizes below 0.5 μm, both positive and negative deep-UV chemically amplified photoresists are generally used. Some useful photoresists are commercially available from Olin Microelectronics, Shipley Company, Clariant Corporation, Tokyo Ohka Kogyo, or JSR Microelectronics.

In FIG. 1D, CMP is used to remove and planarize sacrificial layer 30. Sacrificial layer 30 is polished back until sacrificial layer 30 is co-planar with first oxide layer 20 located on the top surface of features 10. Preferably, the polishing composition or method chosen should remove the sacrificial material at a much faster rate than that of the oxide material. Most preferably, the polishing selectivity of sacrificial material to oxide should be greater than 10:1.

In a typical CMP process step, the substrate surface that is being polished is placed in contact with a rotating polishing pad. A carrier applies pressure against the backside of the substrate. During the polishing process, the pad and table are rotated while a downward force is maintained against the substrate back. A chemically reactive solution is applied to the pad during polishing. The chemically reactive solution is formulated to include chemicals that react with and soften the surface of the material being polished. The polishing process further requires an abrasive material to assist in removing a portion of the substrate surface that has been softened by a reaction between the polishing composition and the substrate surface material. The abrasive may be incorporated into the polishing pad, into the chemically reactive polishing composition or both. Ingredients in the polishing composition or slurry initiate the polishing process by chemically reacting with material on the surface of the substrate that is being polished. The polishing process is facilitated by the rotational movement of the pad relative to the substrate as the chemically reactive polishing composition or slurry is provided to the substrate/pad interface. Polishing is continued in this manner until the desired film or amount of film on the substrate surface is removed.

The choice of polishing composition or slurry is an important factor in the CMP step. Depending on the choice of ingredients such as oxidizing agents, film forming agents, acids, bases, surfactants, complexing agents, abrasives, and other useful additives, the polishing slurry can be tailored to provide effective polishing of the substrate layer(s) at desired polishing rates while minimizing surface imperfections, defects and corrosion and erosion. Furthermore, the polishing composition may be selected to provide controlled polishing selectivities to other thin-film materials used in substrate manufacturing.

Examples of CMP polishing compositions and slurries are disclosed, in U.S. Pat. Nos. 6,068,787, 6,063,306, 6,033,596, 6,039,891, 6,015,506, 5,954,997, 5,993,686, 5,783,489, 5,244,523, 5,209,816, 5,340,370, 4,789,648, 5,391,258, 5,476,606, 5,527,423, 5,354,490, 5,157,876, 5,137,544, 4,956,313, the specifications of each of which are incorporated herein by reference.

In FIG. 1E, a second layer of oxide material 40 is deposited onto the coplanar surface of first oxide layer 20 and sacrificial material layer 30. The thickness of second oxide layer 40 will typically range from about 5000 Å to about 10,000 Å. In FIG. 1F, second oxide material layer 40 is etched to form void features 50 that can be used as vias or trenches. Vias are holes that connect one level of metal with the overlying and underlying level. Trenches form the interconnecting “wires” embedded in the oxide material.

In FIG. 1F, sacrificial material layer 30 is removed using etch techniques to leave an air filled voids 60, having a dielectric constant value of about 1.0, in the space previously occupied by the sacrificial polymer 30. Preferred etch techniques include vapor etching and plasma etching with oxygen. Optionally, UV light or a light at a desired wavelength may be used to (1) assist the vapor etching techniques in removing sacrificial material layer 30 or (2) remove sacrificial material layer 30, in processes where a laser is needed to initiate a surface chemical reaction. The wavelength of the light can be selected to optimize the removal process. Preferably, the wavelength of the light is such that the optical absorption of the light in the material above sacrificial layer 30 is minimal, while optical absorption of the light in sacrificial layer 30 is maximal. In this way, most of the light will be absorbed in sacrificial layer 30, causing maximum amount of heating and enhanced surface chemical reaction.

In FIG. 1G, a second material layer 70 is deposited onto second oxide layer 40 and into void features 50 etched into second oxide layer 40 to form the next level of metalization, which is connected to the features 10 of the first material layer through void features 50. The steps illustrated in FIGS. 1D-1F are then repeated with second material layer 70. Second material layer 70 is patterned, followed by deposition of a third oxide layer 75, deposition of a second layer of sacrificial material 80, and polishing of second sacrificial layer 80 until sacrificial layer 80 is co-planar with third oxide layer 75 at the interface between sacrificial layer 80 and third oxide layer 75. Then a forth layer of oxide material 85 is deposited onto second sacrificial layer 80. Finally, second sacrificial layer 80 is removed. The steps depicted in FIGS. 1D-1F can be repeated multiple times to form multiple layers on an IC device.

Preferably, each layer of sacrificial material is removed prior to the subsequent deposition of material forming the next level of metalization. Alternatively, all of the sacrificial material may be removed in a single step after all the layers of the IC device have been formed, or after every 2 to 3 layers of the IC conductive layers have been formed.

In order to insure a pathway for the etching vapor to reach all of the sacrificial material 30, the layout of the patterning for each material layer, particularly the lay out of the patterning of void features, may be designed to highly connect the sacrificial layers to each other in order to maximize the low-k regions and minimize the number of required etching vapor openings. Through the process of this invention, low-k regions with k value as low as 1 are generated between metal layers.

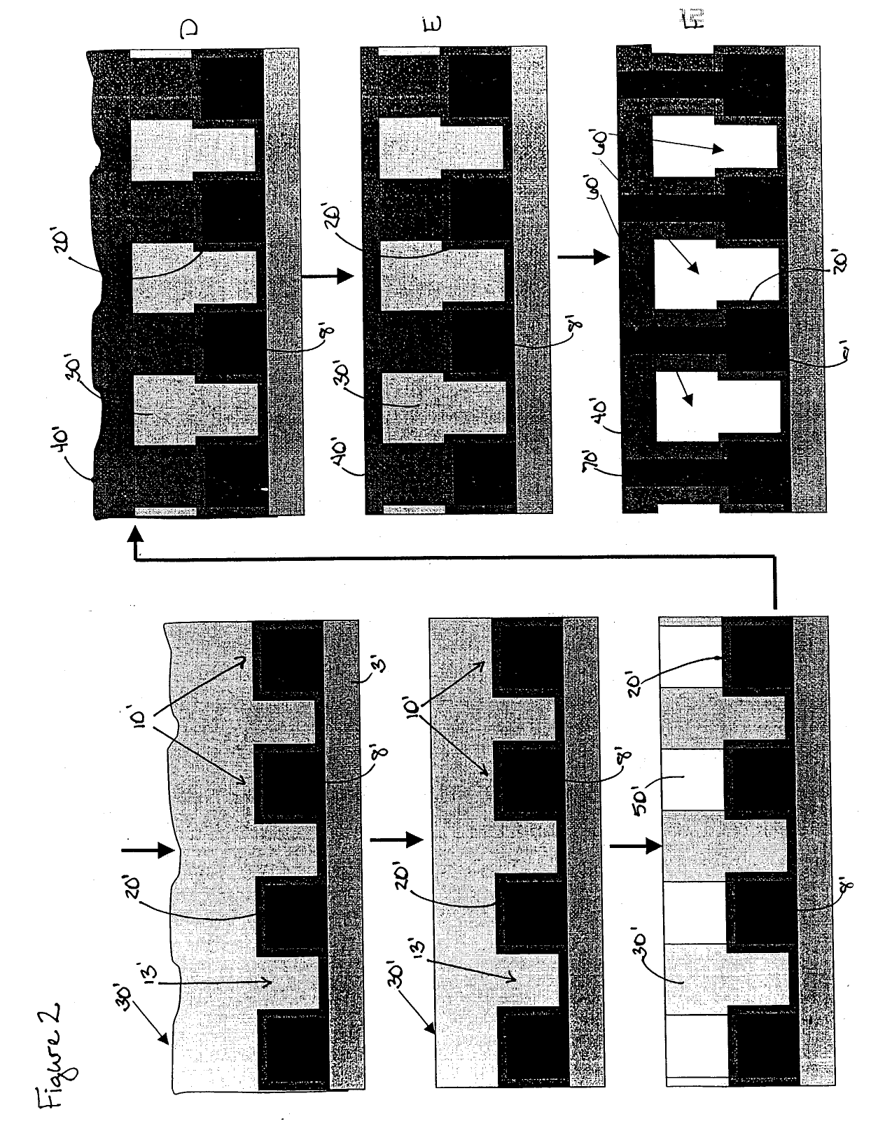

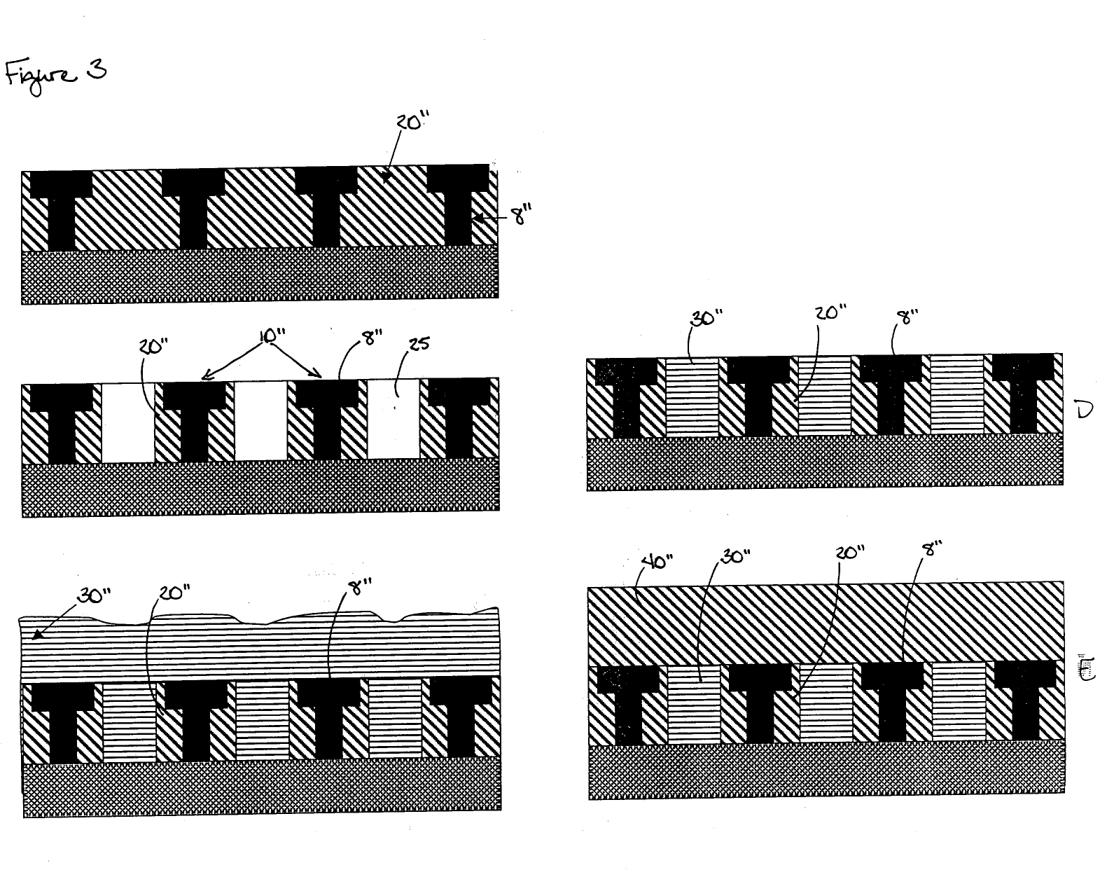

If a further reduction in the capacitance between metal layers is desired, then an alternative embodiment of the disclosed process may be used to maximize the volume of the ultra low-k region. In this alternative process, shown in FIGS. 2A-2F, first material layer 8′ is patterned to form a plurality features 10′ and gaps 13′ between features 10′, followed by deposition of first oxide layer 20′, and deposition of sacrificial layer 30′ in FIG. 2A. Generally, the thickness of sacrificial layer 30′ is about 7000 Å to about 15,000 Å. A larger amount of sacrificial material 30′ is needed because, as shown in FIG. 2B, CMP is used to planarize sacrificial layer 30′ above the interface between oxide layer 20′ and sacrificial layer 30.′ The amount of sacrificial material 30′ removed during this CMP step is about 3000 Å to about 7000 Å.

In FIG. 2C, sacrificial layer 30′ is patterned to form enlarged void features 50′ that can be used as vias or trenches. Void features 50′ patterned at this step need to be about 20% to 50% larger than the final, desired via or trench size because second oxide layer 40′ will occupy a portion of the void feature space.

In FIG. 2D, second layer of oxide material 40′ is deposited onto sacrificial layer 30′ and into void features 50′. Generally, the thickness of second oxide layer 40′ is about 7000 Å to about 15,000 Å.

In FIG. 2E, CMP is used to planarize second oxide layer 40′, until second oxide layer 40′ has a thickness of about 2000 Å to about 5000 Å above sacrificial layer 30′. Next, as shown in FIG. 2F, second oxide layer 40′ is patterned to form void features 50′ in second oxide layer 40′. Then second material layer 70′ is deposited onto second oxide layer 40′ and into void features 50′. Following deposition of second material layer 70′, CMP is used to polish second metal layer 70′ until second material layer 70′ is coplanar with second oxide layer 40′. Finally, as shown in FIG. 2F, sacrificial material layer 30′ is removed. This alternative embodiment results in an increased volume, compared with the previously described embodiment, of low-k region with a dielectric constant of 1.

The use of a sacrificial material not only allows the formation of an ultra low-k region (k=1), but also provides enhanced process robustness, repeatability, and manufacturability. The use of CMP and integration of sacrificial materials 30 is easier than that of current ultra low-k materials due to better material properties (i.e., stability, mechanical strength, etc.) of the sacrificial materials. Further, the processes disclosed above eliminate the needs for direct patterning of ultra low-k materials using lithography and etch processes, which have been shown to be very difficulty for ultra low-k materials.

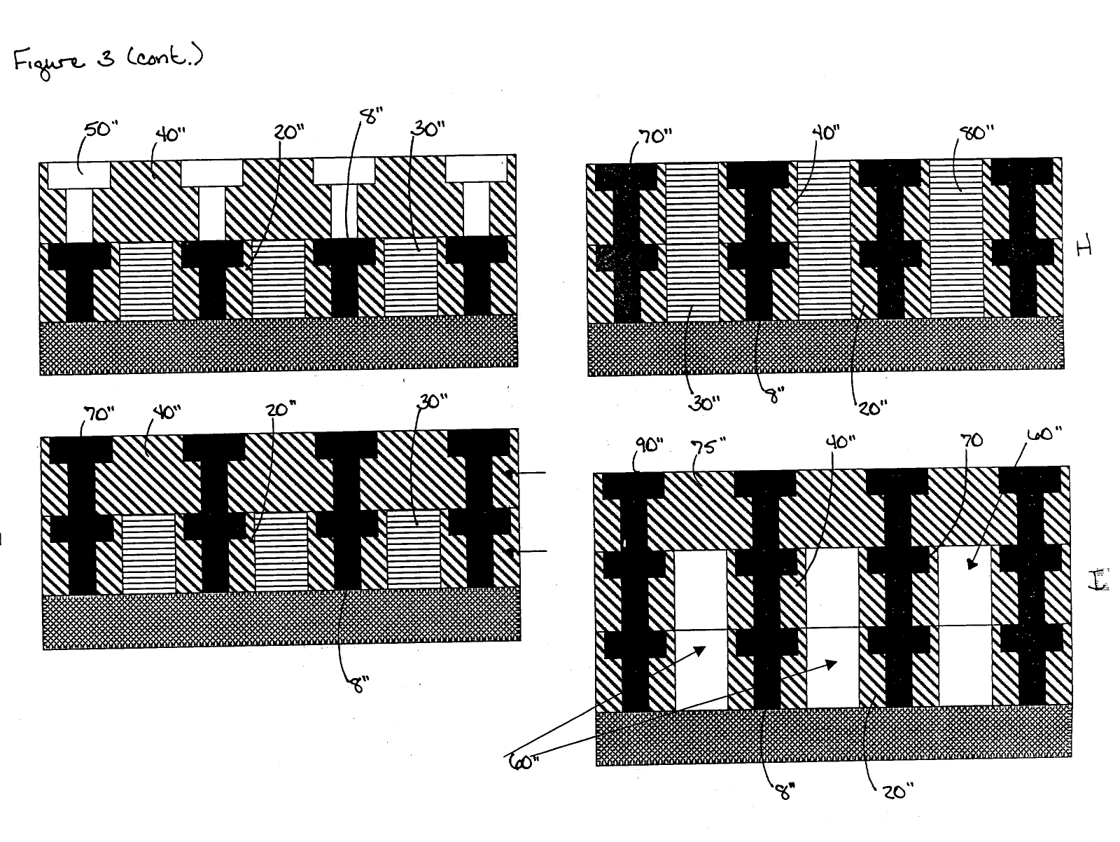

If the present invention is used in conjunction with a damascene process, an alternative embodiment of the present invention may be employed. In FIG. 3A, a damascene process is used to create a first material 8″ patterning within first oxide layer 20.″ Examples of damascene processes are disclosed in U.S. Pat. Nos. 4,789,648 and 5,091,289. In FIG. 3B, a portion of first oxide layer 20″ located between features 10″ of first material 8″ patterning is removed, creating gaps 25 in first oxide layer 20.″

In FIG. 3C, sacrificial material layer 30″ is deposited onto the exposed surface of patterned first oxide layer 20″ and into gaps 25 within first oxide layer 20.″ The thickness of the deposited sacrificial material layer 30″ should be sufficient to fill gaps 25. CMP is then used to remove excess sacrificial material 30″ from the surface of patterned first oxide layer 20,″ as shown in FIG. 3D.

In FIG. 3E, a second oxide layer 40″ is deposited onto the planarized surface of patterned first oxide layer 20″ and sacrificial material 30.″ The thickness of second oxide layer 40″ should be essentially equal to the desired height of void features 50″ patterned into second oxide layer 40,″ as shown in FIG. 3F. Damascene is again used to create second material layer 70″ patterning within second oxide layer 40,″ as shown in FIGS. 3F-3G.

In FIG. 3H, a portion of second oxide layer 40″ located between features 10″ of second material 40″ patterning is removed, creating gaps 45. Second layer of sacrificial material 80″ is then deposited upon the surface of second oxide layer 40″ and into gaps 45 within second oxide layer 40.″ CMP is again used to remove excess sacrificial material 80″ from the surface of second oxide layer 40.″

In FIG. 31, third oxide layer 75″ is deposited onto the planarized surface of second oxide layer 40″ and second sacrificial layer 80.″ Damascene is used once again to pattern third oxide layer 75″ to create features of third material 90″ within third oxide layer 75.″ Finally, sacrificial material 30″ and 80″ are removed to create air filled voids 60″ between the material features patterned within first oxide layer 20″ and second oxide layer 40.″

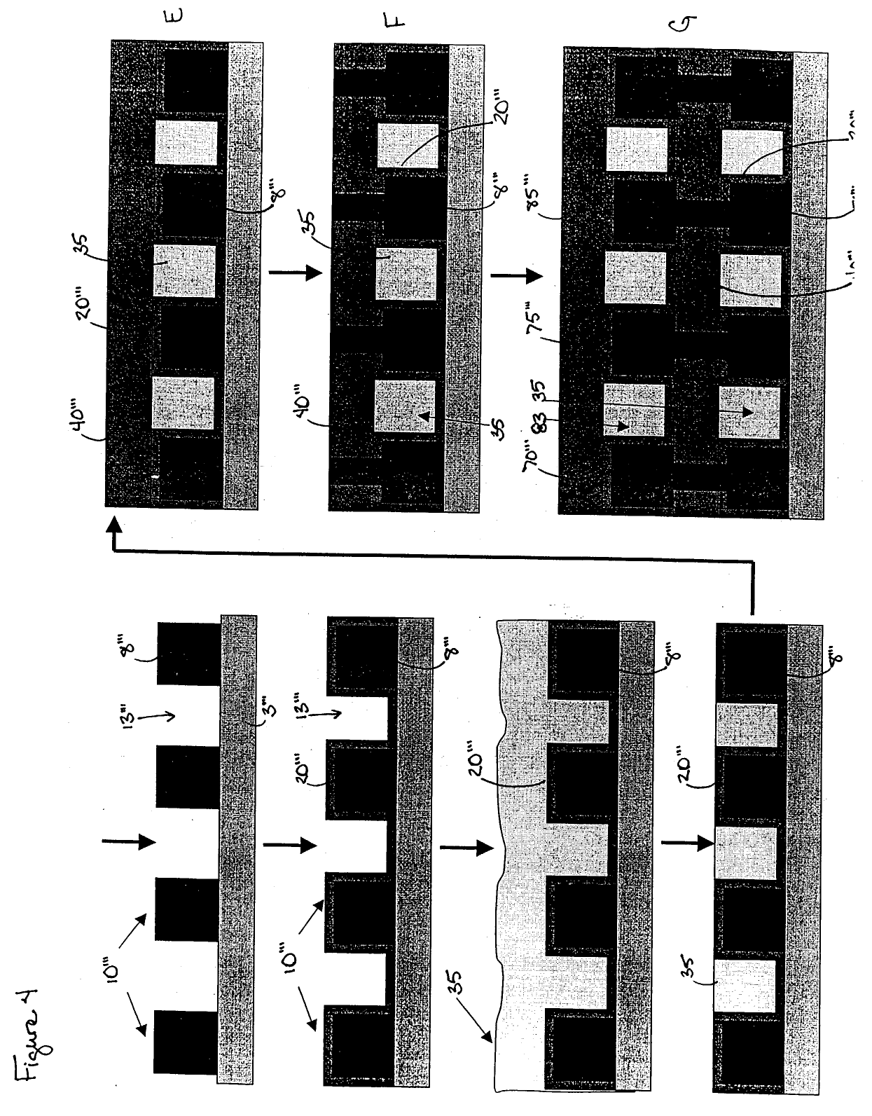

If a sacrificial material cannot be utilized in the fabrication of the IC device, an alternative embodiment of the present invention, using current ultra low-k materials, may be used. In FIGS. 4A and 4B, first material layer is patterned to form features 10′″, followed by deposition of first layer of oxide material 20′″. Next, as is shown in FIG. 4C, a first layer of ultra low-k material 35 is deposited onto first oxide layer 20′″. The thickness deposited of ultra low-k material layer 35 should be sufficient to fill gaps 13′″. The thickness should also be sufficient to achieve planarity of ultra low-k layer 35 after polishing. Generally, the thickness of ultra low-k layer 35 will range from about 5000 Å to about 15,000 Å. Ultra low-k layer 35 may be deposited onto first oxide layer 20′″ by spin-on or chemical vapor deposition techniques.

Ultra low-k material 35 is preferably selected from materials having a k value that is equal to or below 2.2 and that has sufficient mechanical stability to withstand CMP. Examples of useful ultra low-k materials include, but are not limited to Si—O—C, such as the one manufactured by Applied Materials, porous silicon, manufactured by Honeywell and Dow Corning, and PTFE-based materials, manufactured by W. L. Gore.

In FIG. 4D, CMP is used to remove excess ultra low-k material 35 and to planarize ultra low-k layer 35. Ultra low-k layer 35 is polished to form a co-planar surface comprising first oxide layer 20′″ and ultra low-k layer 35.

In FIG. 4E, a second layer of oxide material 40′″ is deposited onto the coplanar surface of first oxide layer 20′″ and ultra low-k layer 35. Generally, the thickness of second oxide layer 40′″ will range from about 5000 Å to about 10,000 Å. Then, in FIG. 4F, this second layer of oxide material 40′″ is etched to form void features 50′″. Second material layer 70′″ is deposited onto second oxide layer 40′″ and into void features 50′″ etched into second oxide layer 40′″. The second material 70′″ above the surface of the second oxide layer 40′″ is then removed using CMP. After creation of void space between the second material 70′″, the steps illustrated in FIGS. 4C-4E are then repeated with second material layer 70′″. Deposition of a second layer of ultra low-k material 83, and polishing of second ultra low-k layer 83 until ultra low-k layer 83 is co-planar with third oxide layer 75′″ at the interface between ultra low-k layer 83 and third oxide layer 75′″. Then forth layer of oxide material 85′″ is deposited onto second ultra low-k layer 83.

The advantage of this embodiment of the present invention is that it significantly reduces or eliminates the integration issues with ultra low-k materials since etching, deposition of the metal layers, and lithography are now performed within an oxide layer. Therefore, manufacturability of IC devices incorporating ultra low-k materials is significantly improved.

It should be understood that a wide range of changes and modifications could be made to the embodiments of the process described above. For instance, the basic process disclosed in the present invention can be applied to the manufacture of other substrates utilizing metal and dielectric thin film layers. It is therefore intended that the foregoing description illustrates, rather than limits this invention, and that it is the following claims, including all equivalents, which define this invention.

1. A method for fabricating an integrated circuit having an ultra low-k region, comprising the steps of:
a) forming a substrate having a first material layer;
b) patterning the first material layer to form a plurality of features each having a top surface and to form gaps between the features;
c) depositing a first oxide material layer onto the top surface of the features and into the gaps;
d) depositing a first sacrificial material layer onto the first oxide layer;
e) polishing the first sacrificial layer to form a co-planar surface comprising the first sacrificial layer and the first oxide layer on the top surface of the features, wherein sacrificial material remains in the gaps;
f) depositing a second oxide layer onto the co-planar surface;
g) patterning the second oxide layer to create a plurality of void features, wherein at least one void feature exposes a portion of the first material layer;
h) depositing a second material layer onto the top surface of the second oxide layer and into the void features; and
i) removing at least a portion of the first sacrificial material.

2. The method of claim 1 wherein steps (b) through (i) are repeated at least once.

3. The method of claim 1 wherein steps (b) through (h) are repeated following step (h).

4. The method of claim 1 wherein the first material layer and the second material layer are conductive material layers.

5. The method of claim 4 wherein at least one conductive material is selected from the group consisting of Al, Cu, W, TiN, Ti, TiW, Ta, TaN, Au, alloys thereof and combinations thereof.

6. The method of claim 1 wherein the first oxide layer is deposited such that the first oxide layer conforms to the features and gaps.

7. The method of claim 1 wherein the first oxide material layer and the second oxide material layer have a thickness of about 500 to about 3,000 Å.

8. The method of claim 1 wherein the first oxide material layer and the second oxide material layer are a material selected from the group consisting of silicon dioxide (SiO2), boron-phosphorous-silica-glass (BPSG), fluorinated oxides (FSG), and phosphorous-silica-glass (PSG).

9. The method of claim 1 wherein the sacrificial material is a spin-on polymer.

10. The method of claim 1 wherein the sacrificial material is a polyimide.

11. The method of claim 1 wherein the sacrificial material is a poly(alylene)ether.

12. The method of claim 1 wherein the sacrificial material is a photoresist.

13. The method of claim 1 wherein the first sacrificial material layer has a thickness of about 5,000 to about 15,000 Å.

14. The method of claim 1 wherein the first sacrificial material layer is polished by chemical mechanical polishing.

15. The method of claim 1 wherein the first sacrificial material layer in step (i) is removed using etch techniques.

16. The method of claim 15 wherein the etch technique used is plasma etch containing oxygen.

17. The method of claim 15 wherein UV light is used in removing the remaining sacrificial material.

18. A method for fabricating an integrated circuit having an ultra low-k-region, comprising the steps of:
a) forming a substrate having a first material layer;
b) patterning the first material layer to form a plurality of features, each having a top surface, and to form gaps between the features;
c) depositing a first oxide material layer onto the top surface of the features and into the gaps;
d) depositing a first sacrificial material layer onto the first oxide layer;
e) planarizing the first sacrificial layer;
f) patterning the first sacrificial layer to form a plurality of void features;
g) depositing a second oxide material layer onto patterned first sacrificial layer and into the void features;
h) planarizing the second oxide layer;
i) patterning the second oxide layer to form a plurality of void features wherein at least one void feature exposes a portion the first material layer;
j) depositing a second material layer onto the second oxide layer and into the void features;
k) polishing the second material layer to form a co-planar surface comprising the second material layer and the second oxide layer, wherein second material remains in the void features; and
l) removing at least a portion of the first sacrificial material.

19. The method of claim 18 wherein steps (a) through (l) are repeated at least once.

20. The method of claim 18 wherein steps (a) through (k) are repeated at least once following step (k).

21. The method of claim 18 wherein the first material layer is a conductive material.

22. The method of claim 21 wherein the conductive material is selected from the group consisting of Al, Cu, W, TiN, Ti, TiW, Ta, TaN, Au, alloys thereof and combinations thereof.

23. The method of claim 18 wherein the first oxide layer is deposited such that that first oxide layer conforms to the features and gaps.

24. The method of claim 18 wherein the first oxide material layer and the second oxide material layer have a thickness of about 500 to about 3,000 Å.

25. The method of claim 18 wherein the first oxide material layer and the second oxide material layer are selected from the group consisting of silicon dioxide (SiO2), boron-phosphorous-silica-glass (BPSG), fluorinated oxides (FSG), and phosphorous-silica-glass (PSG).

26. The method of claim 18 wherein the first sacrificial material layer is a spin-on polymer.

27. The method of claim 18 wherein the sacrificial material is a polymer.

28. The method of claim 18 wherein the sacrificial material is a poly(alylene)ether.

29. The method of claim 18 wherein the sacrificial material is a photoresist.

30. The method of claim 18 wherein the sacrificial material layer has a thickness of about 7,000 to about 15,000 Å.

31. The method of claim 18 wherein the planarizing of the first sacrificial layer in step (e) and the second oxide layer in step (h), and the polishing of the second material layer in step (k) are perfomed by chemical mechanical polishing.

32. The method of claim 18 wherein the first sacrificial layer is removed in step (l) using plasma etch techniques.

33. The method of claim 18 wherein vapor etching is used in step (l) in the removal of sacrificial material.

34. The method of claim 18 wherein UV light is used in step (l) in the removal of sacrificial material.

35. A method for fabricating an integrated circuit having an ultra low-k region, comprising the steps of:
a) applying a first oxide layer on top of a substrate;
b) patterning the first oxide layer and depositing a first material layer to form a plurality of first material features within the first oxide layer;
c) removing a portion of the first oxide layer between the first material features thereby creating gaps in the first oxide layer;
d) depositing a first sacrificial material layer onto the surface of the patterned first oxide layer and into the gaps within the first oxide layer;
e) polishing the first sacrificial layer to form a co-planar surface comprising the first sacrificial layer and the first oxide layer, wherein first sacrificial material remains in the gaps;
f) depositing a second oxide layer onto the co-planar surface;
g) patterning the second oxide layer to create a plurality of void features, wherein at least one void feature exposes a portion of the first material layer;
h) depositing a second material layer onto the top surface of the second oxide layer and into the void features, thereby creating second material features;
i) removing a portion of the second material layer from the second oxide layer surface;
j) removing a portion of the second oxide layer between the second material features thereby creating gaps in the second oxide layer;
k) depositing a second sacrificial material layer onto the surface of the patterned second oxide layer and into the gaps within the second oxide layer;
l) polishing the second sacrificial layer to form a co-planar surface comprising the second sacrificial layer and the second oxide layer, wherein second sacrificial material remains in the gaps;
m) depositing a third oxide layer onto the co-planar surface;
n) patterning the third oxide layer to create a plurality of void features, wherein at least one void feature exposes a portion of the second material layer;
o) removing at least a portion of the first sacrificial material layer and the second sacrificial material layer.

36. The method of claim 35 wherein steps (c) through (o) are repeated at least once.

37. The method of claim 35 wherein steps (c) through (n) are repeated following step (n).

38. The method of claim 35 wherein the first material layer, the second material layer and third material layer are conductive material layers.

39. The method of claim 38 wherein at least one conductive material is selected from the group consisting of Al, Cu, W, TiN, Ti, TiW, Ta, TaN, Au, alloys thereof and combinations thereof.

40. The method of claim 35 wherein the first oxide material layer, second oxide material layer, and third oxide material layer are selected from the group consisting of silicon dioxide (SiO2), boron-phosphorous-silica-glass (BPSG), fluorinated oxides (FSG), and phosphorous-silica-glass (PSG).

41. The method of claim 35 wherein damascene techniques are used to define material layers.

42. The method of claim 35 wherein the sacrificial material is a spin-on polymer.

43. The method of claim 35 wherein the sacrificial material is a polyimide.

44. The method of claim 35 wherein the sacrificial material is a poly(alylene)ether.

45. The method of claim 35 wherein the sacrificial material is a photoresist.

46. The method of claim 35 wherein the sacrificial layer is polished in steps (e) and (1) by chemical mechanical polishing.

47. The method of claim 35 wherein the first sacrificial material layer and the second sacrificial material layer are removed using etch techniques.

48. The method of claim 47 wherein the etch technique used is plasma etch containing oxygen.

49. The method of claim 47 wherein UV light is used to assist the removal of sacrificial material.

50. A method for fabricating an integrated circuit having an ultra low-k region, comprising the steps of:
a) forming a substrate having a first material layer;
b) patterning the first material layer to form a plurality of features, each having a top surface, and to form gaps between features;
c) depositing a first oxide material layer onto the top surface of the features and into the gaps;
d) depositing a first ultra low-k material layer onto the first oxide layer;
e) polishing the first ultra low-k layer to form a co-planar surface comprising the first ultra low-k layer and the first oxide material layer on the top surface of the features, wherein ultra low-k material remains in the gaps between features;
f) depositing a second oxide material layer onto the co-planar surface
g) patterning the second oxide material layer to create a plurality of void features, wherein at least one void feature exposes a portion of the first material layer; and
h) depositing a second material layer onto the top surface of the second oxide material layer and into the void features.

51. The method of claim 50 wherein steps (b) through (h) are repeated at least once.

52. The method of claim 50 wherein the first material layer and the second material layer are conductive material layers.

53. The method of claim 52 wherein at least one conductive material is selected from the group consisting of Al, Cu, W, TiN, Ti, TiW, Ta, TaN, Au, alloys thereof and combinations thereof.

54. The method of claim 50 wherein the first oxide layer is deposited such that the first oxide layer conforms to the features and gap.

55. The method of claim 50 wherein the first oxide material layer and second oxide material layer are selected from the group consisting of silicon dioxide (SiO2), boron-phosphorous-silica-glass (BPSG), fluorinated oxides (FGS), and phosphorous-silica-glass (PSG).

56. The method of claim 50 wherein the ultra low-k material has a dielectric constant of less than or about 2.2.

57. The method of claim 50 wherein the first ultra low-k layer is polished by chemical mechanical polishing.
